(19) United States
(12) Patent Application Publication
(10) Pub. No.: US 2026/0105959 A1
(43) Pub. Date: Apr. 16, 2026

(54) CURRENT-MODE OPERATION OF ANALOG CONTENT ADDRESSABLE MEMORIES

(71) Applicant: Hewlett Packard Enterprise Development LP, Spring, TX (US)

(72) Inventors: Luca Buonanno, Fort Collins, CO (US); Giacomo Pedretti, San Francisco, CA (US); Lei Zhao, Fort Collins, CO (US); James Ignowski, Fort Collins, CO (US)

(21) Appl. No.: 18/914,938

(22) Filed: Oct. 14, 2024

(51) Int. Cl. G11C 15/04; G11C 13/00

(52) U.S. Cl. CPC G11C 15/046; G11C 13/0069

(57) ABSTRACT

In certain examples, an analog content addressable memory (ACAM) component includes a plurality of transistors and a memristor. A gate terminal of a first transistor of the plurality of transistors is coupled to a data line for applying an input current, another terminal of the first transistor is coupled to the memristor and a gate terminal of a second transistor, another terminal of the second transistor is coupled to a match line, and the ACAM component is configured to provide a match result based on the input current and a value programmed to the memristor.

### BACKGROUND

Machine learning algorithms are often executed using computing resources. Such computing resources are often used to process data, perform training of machine learning algorithms, and execute trained machine learning models to generate results.

### BRIEF DESCRIPTION OF THE DRAWINGS

Certain examples discussed herein will be described with reference to the accompanying drawings listed below. However, the accompanying drawings illustrate only certain aspects or implementations of examples described herein by way of example, and are not meant to limit the scope of the claims. Aspects of the present disclosure are best understood from the following detailed description when read with the accompanying figures. For a more complete understanding of this disclosure, and advantages thereof, reference is now made to the following descriptions taken in conjunction with the accompanying drawings, in which:

FIG. 1 is a block diagram of a computing system, in accordance with to one or more examples disclosed herein.

FIG. 2 is a block diagram of an accelerator, in accordance with to one or more examples disclosed herein.

FIG. 3 is a circuit diagram of an analog content addressable memory (ACAM) cell implementing an upper bound, in accordance with to one or more examples disclosed herein.

FIG. 4 is a circuit diagram of an analog content addressable memory (ACAM) cell implementing an upper bound, in accordance with to one or more examples disclosed herein.

FIG. 5 is a block diagram of an ACAM cell for general computing, in accordance with to one or more examples disclosed herein.

The figures are drawn to illustrate various aspects of the disclosure and are not necessarily drawn to scale.

### DESCRIPTION

The following disclosure provides many different examples for implementing different features. Specific examples of components and arrangements are described below to simplify the present disclosure. These are, of course, merely examples and are not intended to be limiting.

Machine learning (ML) models may be employed to perform a variety of tasks. ML models may be provided training data, from which the ML model may learn. A trained ML model may be provided input data and, based on the training previously performed, generate an output. As an example, such ML models may include, but are not limited to, decision trees, random forests, and large language models using transformers.

Execution of such ML models may benefit from the use of accelerators for performing various computations, calculations, operations, and the like. Accelerators may be elements included in and/or operatively connected to a computing device that are configured to improve execution of operations performed by the computing device (e.g., increase execution speed, reduce execution time, and the like). As an example, such accelerators may include dot product engines (e.g., arrays of memristors or resistive elements) for performing matrix-vector multiplications (e.g., for performing dimensionality reductions of a feature space), and analog content addressable memory (ACAM) elements for implementing at least a portion of the execution of an ML model (e.g., implementing a decision tree).

In general, an ACAM element may be an array of ACAM cells. Each ACAM cell may store a value, or range of values, against which inputs may be tested to determine whether the input matches the value stored in an ACAM cell and/or falls within a range of values stored in an ACAM cell.

When using one or more ACAMs cells and/or arrays as part of an accelerator in such scenarios, the ACAMs may be configured to receive analog inputs. The analog inputs may be provided to cells of circuitry of an ACAM array, which are configured to test the input against values stored in the ACAM cell. As an example, such circuitry of an ACAM cell and/or ACAM array may include any number of transistors and memristors. The memristors may be configured with conductance values that determine, in conjunction with the transistors, whether a match line remains at a pre-charged high value, indicating that the input value is a match for a particular ACAM cell, or is discharged, indicating a mismatch of the input value for the ACAM cell.

Series of such ACAM cells (e.g., arranged in rows) may thus be used to test input analog values against any number of values stored in ACAM cells, with the test determining if the input value is above a threshold, below a threshold, or within a range, defined by the values of the memristors in the ACAM cells. Such ACAM cells may be arranged in arrays for testing multiple input analog values, such as, for example, analog values corresponding to a vector output from a dot product engine and resulting from a matrix-vector multiplication performed therein.

As an example, a dot product engine may output a set of values that represent the vector result of a vector matrix multiplication. Analog values corresponding to the vector may be provided as input to an array of ACAM cells. Each row of the ACAM array may be configured to implement a branch of a decision tree ML model used for classification. Thus, the values input to the ACAM array may be tested against values programmed into the ACAM cells of each row of the ACAM array. The ACAM array may then provide a binary output, where each row either has indicates a match for the branch (as the match line remained high due to the input value matching the conditions implemented in each ACAM cell of the row) or a mismatch (as the match line for the row was discharged due to at least one mismatch between the input value and the conditions implemented in the ACAM cells of the row). The set of outputs from the ACAM array (e.g., per-row matches and mismatches) may be provided to other circuitry or components configured to map the outputs to one or more particular classes (e.g., a match only on row five of the ACAM array corresponds to classifying an image as being of a cat).

However, ACAM arrays often require analog voltages as inputs. In order to provide analog voltages as inputs to an ACAM array often requires a considerable amount of peripheral circuitry to convert non-analog voltages (e.g., digital inputs, analog currents) into analog voltages. As an example, a dot product engine often performs matrix-vector multiplication by applying input vector values to a memristor crossbar array storing a matrix as conductance values programmed to the memristors of the crossbar array. The resulting output from such a crossbar array is generally a summation of current values of columns of the crossbar array, which may, for example, represent a feature vector when the dot product engine is configured to perform dimensionality reduction operations via matrix-vector multiplication. Thus, to provide such an output to an ACAM array for further processing (e.g., applying the feature vector to a decision tree), the output currents from the dot product engine must be converted to voltage values, which may require an amount of additional circuitry for performing the current-to-voltage conversions.

One or more examples disclosed herein address, at least in part, the challenges of using ACAM arrays in accelerators by providing ACAM arrays that include ACAM cells with circuitry configured to use current as input rather than voltages, which may reduce the amount of circuitry in the ACAM cells, and/or reduce or eliminate the need for peripheral circuitry for converting currents to voltages as inputs to the ACAM array.

In one or more examples, a two transistor, one memristor (2T1M) circuit may be used as at least a portion (e.g., an ACAM component) of an ACAM cell implementing an upper bound against which an input current value may be tested, and/or a 2T1M circuit may be used as at least a portion (e.g., an ACAM component) of an ACAM cell implementing a lower bound against which an input current value may be tested. In one or more examples, using a combination of two such ACAM components may be combined in an ACAM cell to implement a range of values, and an input current value may be tested to determine whether it falls within the range.

In one or more examples, a circuit for implementing an upper bound in an ACAM cell includes two transistors and one memristor (e.g., 2T1M). In one or more examples, a conductance value programmed to the memristor corresponds to an upper bound against which an input current value to the ACAM cell may be tested, which determines whether the match line remains high, indicating a match, or is discharged, indicating a mismatch. In one or more examples, a match line is pre-charged to an initial value using an appropriate circuit. In one or more examples, a data line, which is also pre-charged to high, is connected to a gate terminal of a first transistor, and another terminal of the transistor is connected to the memristor and to the gate terminal of a second transistor, which has another terminal connected to a match line. In one or more examples, because the data line is pre-charged to high, the gate of the second transistor is kept at high, leaving the match line at high. In one or more examples, when an input current applied to the data line is sufficiently high (e.g., above the upper bound set by the memristor), the branch of the transistor connected to the memristor is sufficiently low that the gate of the second transistor is low, and, thus, the match line discharges, indicating a mismatch for the cell. Conversely, when the input current from the data line is lower than the upper bound set by the memristor, the match line remains high, indicating a match for the ACAM cell.

In one or more examples, a circuit for implementing a lower bound in an ACAM cell includes two transistors and one memristor (e.g., 2T1M). In one or more examples, a conductance value programmed to the memristor corresponds to a lower bound against which an input current value to the ACAM cell may be tested, which determines whether the match line remains high, indicating a match, or is discharged, indicating a mismatch. In one or more examples, a match line is pre-charged to an initial value using an appropriate circuit. In one or more examples, a data line, which is also pre-charged to high, is connected to a gate terminal of a first transistor, and another terminal of the transistor is connected to the memristor and to a gate terminal of a second transistor, which has another terminal connected to a match line. In one or more examples, the data line in the lower bound ACAM cell is also connected to a current pull down component. In one or more examples, if an input current applied to the data line is smaller than a threshold, the current pull down component discharges the data line, thereby discharging the match line (indicating a mismatch). If, on the other hand, the current is above a threshold (e.g., set by the value programmed to the memristor), the data line, and thus the match line, remain charged (indicating a match).

In one or more examples, an ACAM cell for testing whether an input current is within a range may be implemented by combining the upper bound (as a first ACAM component of an ACAM cell) and lower bound (as a second ACAM component of an ACAM cell) versions of the ACAM component as a 4T2M ACAM cell. In one or more examples, such an ACAM cell implementing both the above-described upper and lower bounds has two separate data lines for driving the two portions of the ACAM cell with the same value of input current.

In one or more examples, for either the above-described upper bound or lower bound portions of an ACAM cell, a voltage generator may be connected to the data line to either set the conductance value of the memristor or reset the memristor via application of a voltage to the data line of the ACAM cell that includes the memristor. In one or more examples, the voltage generator is disconnected from the ACAM cell during normal operation of the ACAM cell, and connected to the ACAM cell when values are to be programmed to memristors of the ACAM cell.

In one or more examples, the above-described upper and lower-bound circuits may be combined into larger ACAM cells, which may be used for general computing, such as four-bit, one-variable; eight-bit, one-variable; and four-bit, two-variable computing. Such an ACAM cell, may for example, have similar circuitry for applying an input current separately to different portions of the ACAM cell. Such portions may include a memristor, and transistors. Some of the portions may also include an inverter, while other portions do not include an inverter. In such a configuration, aq match line of the cell is pre-charged to high, and the data line is also pre-charged to high. In one or more examples, if an input current applied falls within a given range defined by the states of the memristors, the match line remains high (indicating a match), otherwise the match line will discharge, indicating a mismatch.

In one or more examples, the above-described circuitry configurations of transistors and memristors are used to implement ACAM cells, which, in turn, may be used to implement ACAM arrays. Such ACAM arrays may be used as at least a portion of accelerator components of a computing device for accelerating certain operations, such as those used in a variety of ML models. Using such accelerators may increase the speed of ML model execution, increase energy efficiency, reduce circuitry area, reduce power dissipation, and/or allow for higher circuit density.

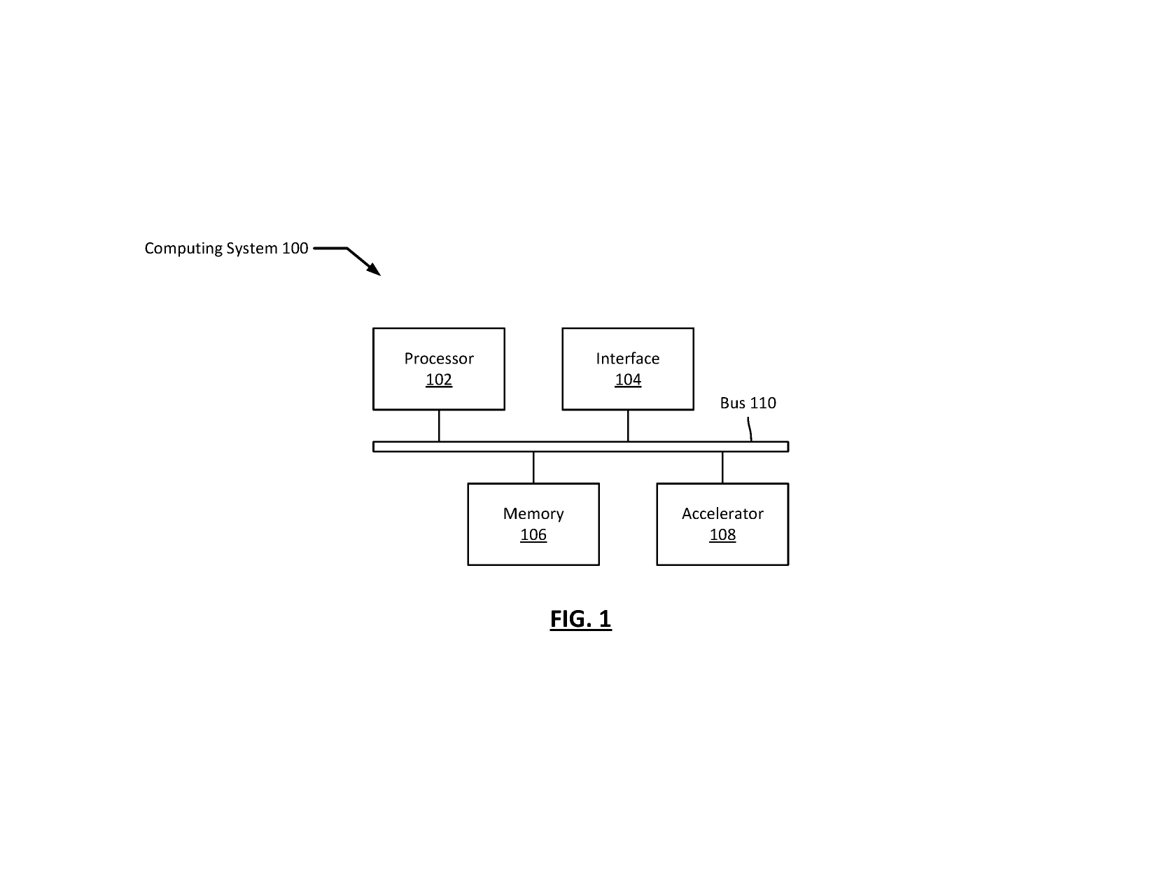

FIG. 1 is a block diagram of a computing system, in accordance with to one or more examples disclosed herein. The computing system 100 may, as an example, be used, at least in part, to execute a ML model. The computing system 100 may, for example, be implemented in an electronic device. Examples of computing systems may include, but are not limited to, a server (e.g., a blade-server in a blade-server chassis, a rack server in a rack, a desktop server, any other type of server device), a desktop computer, a mobile device (e.g., laptop computer, smart phone, personal digital assistant, tablet computer, automobile computing system, and/or any other mobile computing device), a storage device (e.g., a disk drive array, a fibre channel storage device, an Internet Small Computer Systems Interface (iSCSI) storage device, a tape storage device, a flash storage array, a network attached storage device, any other type of storage device), a network device (e.g., switch, router, multi-layer switch, any other type of network device), a virtual machine, a virtualized computing environment, a logical container (e.g., for one or more applications), a container pod, an Internet of Things (IoT) device, an array of nodes of computing resources, a supercomputing device, a data center or any portion thereof, and/or any other type of computing device. As one of ordinary skill in the art will appreciate, any of the aforementioned examples of computing devices necessarily require at least some hardware components. As an example, a virtual machine, a container, and/or a container pod, when considered as a computing device, include the underlying hardware on which the virtual machine, a container, and/or a container pod executes.

The computing system 100 may be utilized in any data processing scenario, including stand-alone hardware, application execution (e.g., mobile applications, server applications, and the like), or combinations thereof. Further, the computing system 100 may be used in any computing network, such as, for example, a public cloud network, a private cloud network, a hybrid cloud network, other forms of networks, or combinations thereof. In one example, the methods provided by the computing system 100 are provided as a service over a network by, for example, a third party, and/or may be executed on computing systems separate from other computing systems or networks. The computing system 100 may be implemented on one or more hardware platforms, in which modules in the system may be executed on one or more platforms. Such modules may run on various forms of cloud technologies and hybrid cloud technologies or be offered as a Software-as-a-Service that may be implemented on or off a cloud network.

To achieve its desired functionality, the computing system 100 includes various hardware components. These hardware components may include a processor 102, an interface 104, a memory 106, and an accelerator 108. The hardware components may be interconnected through a number of busses and/or network connections. In one example, the processor 102, the interface 104, the memory 106, and the accelerator 108 may be communicatively coupled via a bus 110, such as, for example, a PCI-Express bus. Other components for facilitating communication between components of the computing system 100 may be used without departing from the scope of examples disclosed herein. Additionally, although FIG. 1 shows an example of the computing system 100 that includes a single processor 102, memory 106, interface 104, bus 110, and accelerator 108, one or ordinary skill in the art will appreciate that a computing system, such as the computing system 100 may include any number of such components without departing from the scope of examples disclosed herein.

In one or more examples, the processor 102 retrieves executable code from the memory 106 and executes the executable code. The executable code may, when executed by the processor 102, cause the processor 102 to implement all or any portion of the functionality described herein. In one or more examples, the processor 102 may be an integrated circuit for processing instructions. For example, the processor 102 may be one or more cores or micro-cores of a processor. The processor 102 may be a general-purpose processor configured to execute program code included in software executing on the computing system 100. The processor 102 may be a special purpose processor where certain instructions are incorporated into the processor design. The processor 102 may be a central processing unit (CPU), an application specific integrated circuit (ASIC), a graphics processing unit (GPU), a data processing unit (DPU), a tensor processing unit (TPU), an associative processing unit (APU), a vision processing unit (VPU), a quantum processing unit (QPU), and/or various other processing units that use special purpose hardware (e.g., field programmable gate arrays (FPGAs), System-on-a-Chips (SOCs), digital signal processors (DSPs)). Although only one processor 102 is shown in FIG. 1, the computing system 100 may include any number of processors, or a combination of such processors, without departing from the scope of examples disclosed herein.

The interface 104 enables the processor 102 to interact with various other hardware components, external to and/or internal to the computing system 100. For example, the interface 104 may include interface(s) to input/output devices, such as, for example, a display device, a mouse, a keyboard, etc. Additionally, or alternatively, the interface 104 may include interface(s) to storage devices, network devices, host devices, or the like of the computing system 100 or that are operatively connected to the computing system 100 via the interface 104.

The memory 106 may include various types of memory, including volatile and nonvolatile memory. For example, the memory 106 may include Random-Access Memory (RAM), Read-Only Memory (ROM), a Hard Disk Drive (HDD), persistent memory (Pmem) devices, and/or the like. Different types of memory may be used for different data storage needs. For example, the processor 102 may boot from ROM, maintain nonvolatile storage in an HDD, execute program code stored in RAM, and store data under processing in RAM. The memory 106 may include one or more non-transitory computer readable mediums that store(s) instructions for execution by the processor 102. As used herein, the term computer-readable medium includes, but is not limited to, portable or non-portable storage devices, optical storage devices, and various other mediums capable of storing, containing, or carrying instruction(s) and/or data. A computer-readable medium may include a non-transitory medium in which data can be stored and that does not include carrier waves and/or transitory electronic signals propagating wirelessly or over wired connections. Examples of a non-transitory medium may include, but are not limited to, a magnetic disk or tape, optical storage media such as CD or DVD, flash memory, and/or any other memory or memory devices. A computer-readable medium may have stored thereon code and/or machine-executable instructions that may represent a procedure, a function, a subprogram, a program, a routine, a subroutine, a module, a software package, a class, or any combination of instructions, data structures, or program statements. However, when mentioned, non-transitory computer-readable storage media expressly exclude media such as energy, carrier signals, electromagnetic waves, and signals per se.

One or more modules within the computing system 100 may be partially or wholly embodied as software and/or hardware for performing any functionality described herein. For the avoidance of doubt, any software executed by the computing system 100 necessarily executes using at least some portion of the hardware components of the computing system 100.

The accelerator 108, may, for example, be used by the processor 102 to accelerate processing of an ML model. The accelerator 108 is different than the processor 102. The accelerator may include dot product devices for performing matrix-vector multiplication operations, and any number of ACAM components, cells, arrays and the like, and other circuitry components for performing other operations. ACAM elements of the accelerator 108 may be configured to perform any of a variety of predetermined functions having one or more input variables, and may interact with other circuitry to produce outputs that are used in executing an ML model. The accelerator 108 may be able to execute portions of an ML model more efficiently than a general-purpose processor (e.g., the processor 102). Accordingly, the accelerator 108 may improve the performance of the computing system 100.

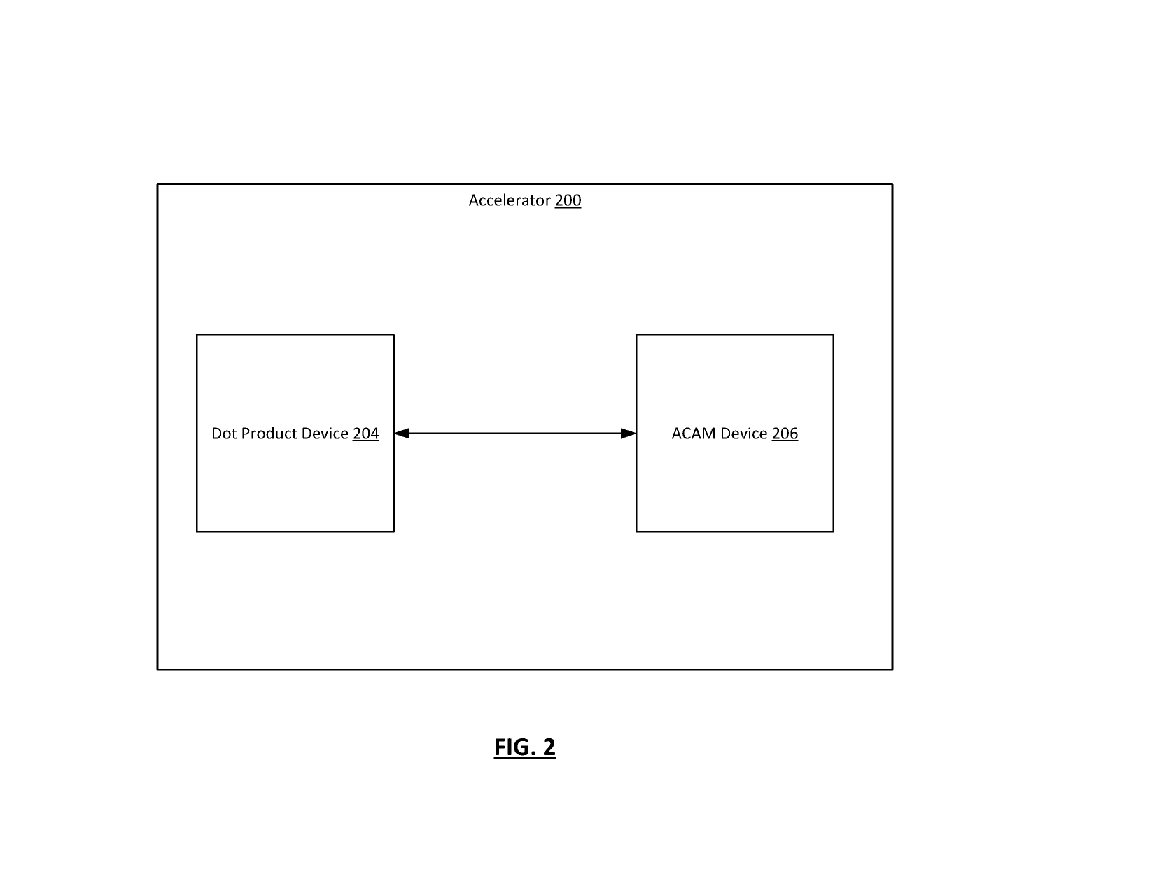

FIG. 2 is a block diagram of an accelerator, in accordance with to one or more examples disclosed herein. The accelerator 200 may be the same as or similar to the accelerator 108 shown in FIG. 1 and discussed above. As shown in FIG. 2, the accelerator 200 includes a dot product device 204, and an ACAM device 206. Each of these components is described below.

In one or more examples, the accelerator 200 is a component of a computing device or computing system. In one or more examples, the accelerator 200 may be one of any number of accelerators of a computing device or system, all or any portion of which may be similar to the accelerator 108. In some examples, a computing device or system may include one or more accelerators such as the accelerator 200, and may also include any number of other types of accelerators (e.g., GPUs). In one or more examples, the accelerator 200 is configured to operate in conjunction with other components of a computing system. In one or more examples, the accelerator 200 is configured to perform various operations, execute instructions, execute algorithms or portions thereof, and the like. The accelerator 200 may perform such operations, execute such instructions, and/or execute such algorithms in a manner that provides improved speed of execution, increases energy efficiency, uses less space, reduces power dissipation, and/or allows for higher component density when compared to computing systems that do not include an accelerator and/or include accelerators of types other than the accelerator 200.

In one or more examples, the accelerator 200 includes the dot product device 204. In one or more examples, the dot product device 204 includes any number of programmable crossbar arrays for executing matrix-vector multiplications. In one or more examples, each programmable crossbar array may be programmed with a matrix. In such an example, an input vector X, which may be a set of digital or analog values, may be provided as input to one or more programmable crossbar arrays of the dot product device to be multiplied, respectively, by the matrices programmed therein.

Any number of programmable crossbar arrays may be included in the dot product device 204 of FIG. 2. In one or more examples, a programmable crossbar array includes a plurality of input electrodes, a plurality of output electrodes and plurality of programmable elements. The input electrodes are arranged in rows, and the output electrodes are arranged in columns. Each programmable element is positioned at a crosspoint or junction of an input electrode and an output electrode. As input, the programmable crossbar array takes a vector of signals (e.g., digital or analog signals) on the input electrodes.

The programmable elements of a programmable crossbar array of the dot product device 204 are circuit elements whose conductance or resistance is programmable. The programmable elements may be non-volatile analog devices, which may be adapted to store one or more bits of data. An example of a programmable element is a memristor, which includes a dielectric layer (e.g., an oxide layer) between two metal layers. When the programmable elements are memristors, the programmable crossbar array is a memristor array. Other examples of programmable elements include multi-bit flash memory cells, resistive random-access memory (ReRAM) cells, phase-change random-access memory (PCRAM) cells, magnetoresistive random-access memory (MRAM) cells, electrochemical random-access memory (ECRAM) cells, and the like.

A programmable crossbar array may also include other peripheral circuitry associated with the programmable crossbar array when used as a storage device. For example, a programmable crossbar array may include drivers connected to the input electrodes. An address decoder may be used to select an input electrode and activate a driver corresponding to the selected input electrode. The driver for a selected input electrode can drive a corresponding input electrode with different voltages corresponding to a vector-matrix multiplication or the process of setting values (e.g., conductance values, resistance values, and the like) within the programmable elements of the programmable crossbar array. Similar driver and decoder circuitry may be included for the output electrodes. Control circuitry may also be used to control application of voltages at the inputs of the programmable crossbar array. Input signals to the input electrodes and output signals from the output electrodes may be analog signals. The peripheral circuitry above described may be fabricated using semiconductor processing techniques in the same integrated structure or semiconductor die as the programmable crossbar array.

A programmable crossbar array may include N input electrodes and M output electrodes. In one or more examples, there are two main operations that occur during operation of a programmable crossbar array. In one or more examples, the first operation is to program the programmable elements in the programmable crossbar array so as to map the values in an N×M matrix to the programmable elements. The second operation is the dot product or matrix-vector multiplication operation. In this operation, input voltages (e.g., the values of a vector representing at least a portion of an input) are applied to the input electrodes and output currents are obtained from the output electrodes, corresponding to the result of multiplying an N×1 vector with the N×M matrices. The input signals may below a threshold of the programming voltage of the programmable elements so the values of the programmable elements in the programmable crossbar array are not changed during the vector-matrix multiplication operation.

As an example, a matrix-vector multiplication may be executed through a programmable crossbar array by applying a set of voltages simultaneously along the input electrodes of the programmable crossbar array and collecting the currents from the output electrodes. The signal (e.g., current) generated on an output electrode is weighted by the corresponding values of the programmable elements at the crosspoints of the output electrode with the input electrodes, and that weighted summation is reflected in the current at the output electrode. Thus, the relationship between the signals at the input electrodes and the currents at the output electrodes is represented by a matrix-vector multiplication of the input vector with the N×M matrix stored as the values of the programmable elements.

The values of programmable elements of a programmable crossbar array of the dot product device 204 may be modified by imposing a voltage across the programmable elements using the input electrodes, the output electrodes, and corresponding voltage drivers. The voltage difference imposed across a programmable element generally determines the resulting value of that programmable element. In some examples, the programming process is performed row-by-row.

In one or more examples, the accelerator 200 includes the ACAM device 206. In one or more examples, the ACAM device 206 includes any number of ACAM arrays. An ACAM array may be an array of ACAM cells (e.g., arranged in rows and columns of the ACAM array). A particular ACAM cell may include any number of ACAM components. An ACAM component may include one or more programmable elements (e.g., memristors) and any number of transistors. An ACAM component may be configured to store a value against which an input to the ACAM device may be compared. An ACAM component may store a value in a programmable element corresponding to an upper bound threshold, a lower bound threshold, or both an upper and lower bound to store a range. In one or more examples, an input to an ACAM component of an ACAM cell of an ACAM array of the ACAM device 206 may be an analog current (e.g., a current that is part of a result output from the dot product device 204). In one or more examples, such a current may be provided as an input to an ACAM cell, or any number of ACAM components therein, and the value of the current may be compared to the values set by the one or more programmable elements of the ACAM components of the ACAM cell. For example, the value of the input current to an ACAM cell may be tested to determine whether the current is below an upper bound threshold, above a lower bound threshold, or within a particular range, any of which may result in an output of the ACAM cell indicating that the input current is a match relative to the value(s) programmed to the programmable elements of the ACAM cell. Conversely, in one or more examples, an ACAM cell may indicate a mismatch if a value of an input current is above an upper bound threshold, below a lower bound threshold, or outside of a value range.

In one or more examples, configuring the circuitry of the ACAM device 206 (e.g., the ACAM components, cells and arrays therein) to accept analog currents as inputs may reduce or eliminate the need for additional circuitry to convert input values to analog voltages. As an example, as discussed above, programmable crossbar arrays of the dot product device 204 may output a set of analog currents. If the ACAM device 206 required input voltages, the accelerator 200 would require additional circuitry to convert the current values to voltage values. In one or more examples, configuring the ACAM device 206 to operate using input currents may reduce or eliminate the need for such additional circuitry.

The ACAM device 206 may be configured to perform any number and/or type of operations, algorithms, and the like. As an example, an ACAM array of the ACAM device 206 may be configured to implement a decision tree, where each row of the ACAM array stores values corresponding to a branch of the decision tree, so that an input current value provided to ACAM cells of the row may be tested against the values corresponding to the programmable elements of the ACAM cells.

In one or more examples, the ACAM device 206 may include components other than ACAM arrays, ACAM cells, and the like, such as pre-charge circuits, search/write circuits, sensing circuits, inverting circuits, format conversion circuits, and the like. Such other components, when used in conjunction with the ACAM arrays, ACAM cells, and/or ACAM components of the ACAM device 206 may allow the ACAM device 206 to perform any number of predetermined functions in order to execute, at least in part, various operations, algorithms, and the like to be performed by the accelerator 200. As such, in one or more examples, a particular portion of the ACAM device 206 may be configured with an ACAM array for computing the result of a particular predetermined function, operation algorithm, and the like, and the ACAM device 206 may include any number of such ACAM arrays without departing from the scope of examples disclosed herein. Thus, the description below sets forth a generalized explanation of the operation of an ACAM array for executing any predetermined functions that an ACAM array may be configured to execute, including ML algorithms (e.g., decision trees), multiplications, exponential functions, logarithmic functions, and the like.

In one or more examples, an ACAM array may be configured to receive any number of input values (e.g., corresponding to one or more inputs to a predetermined function) as input current values and output one or more results (e.g., a binary code corresponding to an output from the predetermined function).

In one or more examples, an ACAM array includes multiple ACAM cells, which may be arranged in rows and columns. The ACAM cells may be programmed with values of programmable elements (e.g., conductance’s, resistances) that correspond to an upper bound, a lower bound, or a range against which an input value to the ACAM array may be tested. One or more range(s) may be programmed for each ACAM cell of an ACAM array. Such ranges may be used to compute the output of a predetermined function.

During a search operation, one or more analog current input values are input to an ACAM array over data lines. One or more ACAM cells in an ACAM array (e.g., a row of ACAM cells, also referred to as an “ACAM row”) then indicates whether the analog current input values are matched by their stored range(s). The stored range(s) encoded in an ACAM cell are compared against a respective analog current input value. Depending on the implementation of an ACAM cell, a match may occur when an analog input value is inside of the range stored in the ACAM cell or a match may occur when an analog input value is outside of the range stored in the ACAM cell (e.g., including above an upper bound or below a lower bound).

In one or more examples, the ACAM device includes any number of pre-charge circuits, which may be configured to pre-charge one or more match lines for one or more ACAM cells (e.g., an ACAM row) of an ACAM array of the ACAM device 206 before a search operation begins. During a search operation, the match line of the ACAM cells remains high to indicate a match if the analog current input values applied to the ACAM cells are matched by the range(s) stored in the ACAM cells. Alternatively, the match line goes low as a current in the match line discharges through pull-down transistors of an ACAM cell to indicate a mismatch if the analog current input values applied to the ACAM cells are not matched by the range(s) stored in the ACAM cells.

In one or more examples, the ACAM device 206 includes one or more sensing circuits, which may sense the outputs of the ACAM cells of an ACAM array. A sensing circuit may include a sense amplifier for each ACAM row of an ACAM array of the ACAM device 206. A match line of each ACAM row may be connected to a sense amplifier. A sense amplifier may be used during a search operation to detect if a match line of an ACAM row is high (indicating a match with one or more analog current input values) or low (indicating a mismatch with the analog current input values).

The ACAM device 206 may be implemented as an integrated circuit (IC) on a semiconductor substrate using suitable microfabrication techniques. Such an IC may integrate the various portions of the ACAM device 206 onto a single chip. The resulting IC may be packaged and integrated into larger systems.

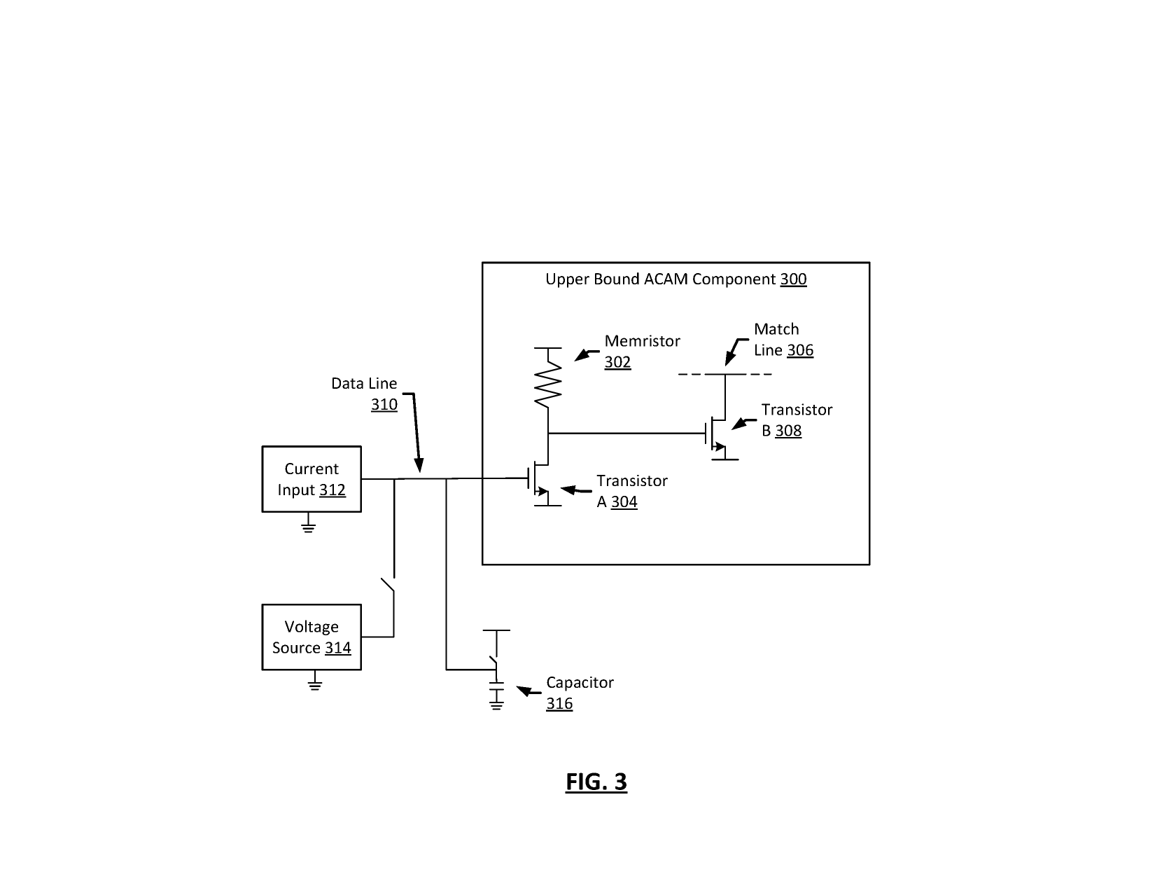

FIG. 3 is a circuit diagram of an analog content addressable memory (ACAM) cell implementing an upper bound, in accordance with to one or more examples disclosed herein. FIG. 3 shows an upper bound ACAM component 300. In one or more examples, the upper bound ACAM component 300 includes circuitry for implementing an upper bound threshold that may be used to test an input current value. In one or more examples, if the input current value is above a threshold corresponding to the value programmed to the upper bound ACAM component 300, the ACAM component 300 will indicate a mismatch. Conversely, in one or more examples, if an input current is less than a threshold corresponding to the value programmed to the upper bound ACAM component 300, the ACAM component 300 will indicate a match.

In one or more examples, the upper bound ACAM component 300 may be used alone as an ACAM cell, or may be incorporated into a larger ACAM cell (e.g., to implement an upper bound of a range to be tested by the ACAM cell). Such an ACAM cell may, for example, be part of an ACAM array of an ACAM device (e.g., the ACAM device 206 of FIG. 2).

In one or more examples, the upper bound ACAM component 300 is a 2T1M ACAM component, including therein two transistors (e.g., transistor A 304, transistor B 308) and one memristor 302. In one or more examples, the transistor A 304 is configured with a gate terminal coupled to a data line 310 to which an input current may be applied (e.g., via current input 312). In one or more examples, the current input 312 may be provided from any source external to the upper bound ACAM component 300. As an example, the current input 312 may correspond to one of a set of currents output from a DPE device (e.g., the dot product device 204 of FIG. 2). In one or more examples, another terminal if the transistor A 304 is connected to the memristor 302 and to a gate terminal of the transistor B 308. In one or more examples, another terminal of the transistor B 308 is connected to a match line 306, which indicates a match when high, and indicates a mismatch when discharged to low (e.g., through the transistor B 308).

In one or more examples, the memristor 302 is programmed with a conductance value that corresponds to an upper bound threshold value against which an input current on the data line 310 may be tested. Programming (or resetting) the memristor 302 may include connecting a voltage source 314 to the data line 310. FIG. 3 shows a state in which the voltage source 314 is not connected, which is the state of the upper bound ACAM component 300 during normal operation, after the memristor 302 has been programmed. In one or more examples, connecting the voltage source 314 applies a bias to the gate terminal of the transistor A to provide a voltage V_{write} to the upper bound ACAM component 300 in order to program the conductance of the memristor 302. Once programmed, the conductance of the memristor 302, in conjunction with the characteristics of the transistors (e.g., 304, 308) corresponds to an upper bound threshold current value.

In one or more examples, a voltage on the match line 306 is pre-charged to high using an appropriate circuit (not shown), and the data line 310 is also pre-charged to high (e.g., via charging the capacitor 316 to an initial voltage value). Thus, the match line 306 may remain high, as the gate of the transistor B 308 is low, so that the match line does not discharge. In one or more examples, if an input current applied via the data line 310 is below the upper bound input current threshold corresponding to the conductance programmed to the memristor (e.g., the input current is sufficiently low), the data line remains charged, and thus the match line remains charged, thereby indicating a match for the input current (as being below the upper bound threshold). In one or more examples, if the input current applied via the data line 310 is above the upper bound input current threshold corresponding to the conductance programmed to the memristor, data line 310 is discharged, and thus the match line 306 will discharge, indicating a mismatch. In one or more examples, this is because when the input current is sufficiently large, the data line is discharged to a point where the current in the circuit branch with the memristor 302 is sufficiently low that the gate of the transistor B 308 is high, and, therefore, the match line 306 is discharged. In one or more examples, the upper bound ACAM component 300 may also be configure to implement a “don’t care” state by programming the memristor such that the match line is not discharged.

Although FIG. 3 shows an example upper bound ACAM component that uses a memristor as a programmable element, one of ordinary skill in the art, having the benefit of this Description, will appreciate that other programmable elements (e.g., resistive elements) may be used without departing from the scope of examples disclosed herein.

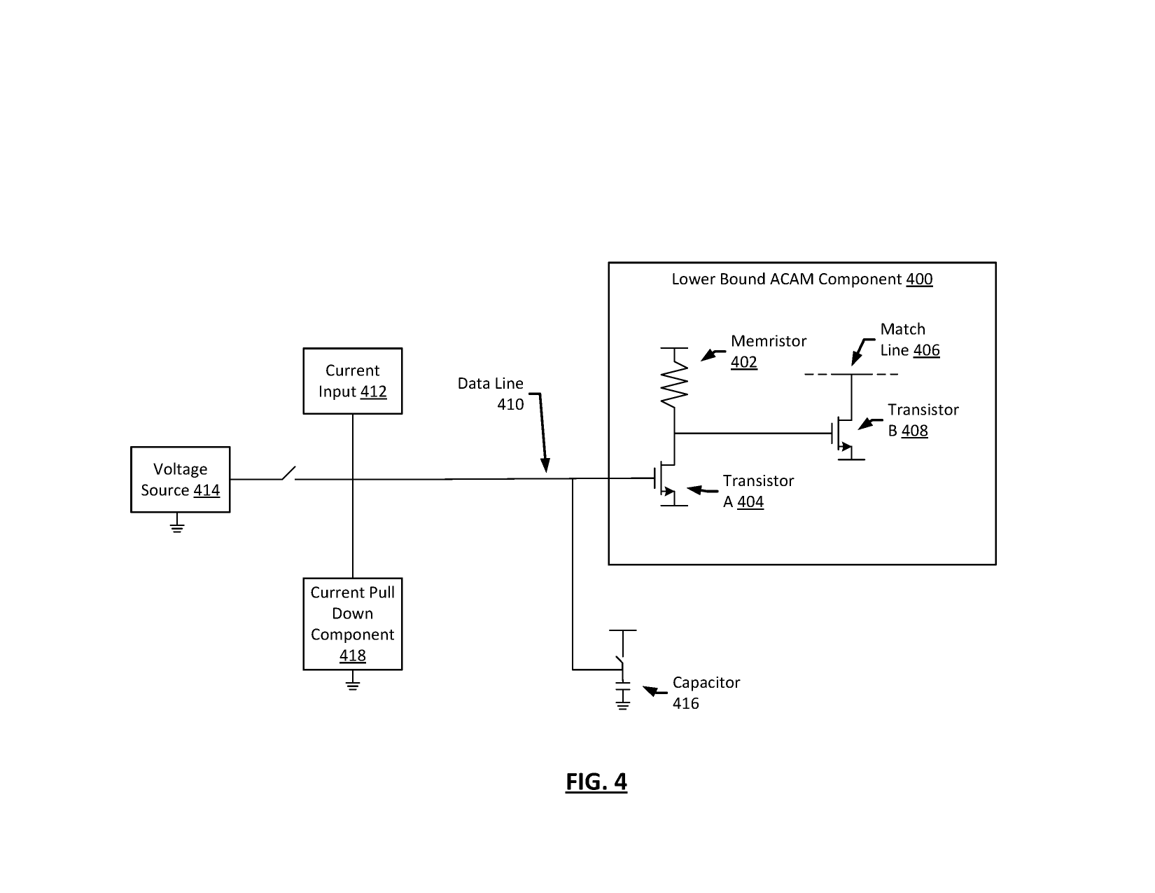

FIG. 4 is a circuit diagram of an analog content addressable memory (ACAM) cell implementing a lower bound, in accordance with to one or more examples disclosed herein. FIG. 4 shows a lower bound ACAM component 400. In one or more examples, the lower bound ACAM component 400 includes circuitry for implementing a lower bound threshold that may be used to test an input current value. In one or more examples, if the input current value is below a threshold corresponding to the value programmed to the lower bound ACAM component 400, the ACAM component 400 will indicate a mismatch. Conversely, in one or more examples, if an input current is above a threshold corresponding to the value programmed to the lower bound ACAM component 400, the ACAM component 400 will indicate a match.

In one or more examples, the lower bound ACAM component 400 may be used alone as an ACAM cell, or may be incorporated into a larger ACAM cell (e.g., to implement a lower bound of a range to be tested by the ACAM cell). Such an ACAM cell may, for example, be part of an ACAM array of an ACAM device (e.g., the ACAM device 206 of FIG. 2).

In one or more examples, the lower bound ACAM component 400 is a 2T1M ACAM component, including therein two transistors (e.g., transistor A 404, transistor B 408) and one memristor 402. In one or more examples, the transistor A 404 is configured with a gate terminal coupled to a data line 410 to which an input current may be applied (e.g., via current input 412). In one or more examples, the current input 412 may be provided from any source external to the lower bound ACAM component 400. As an example, the current input 412 may correspond to one of a set of currents output from a DPE device (e.g., the dot product device 204 of FIG. 2). In one or more examples, another terminal if the transistor A 404 is connected to the memristor 402 and to a gate terminal of the transistor B 408. In one or more examples, another terminal of the transistor B 408 is connected to a match line 406, which indicates a match when high, and indicates a mismatch when discharged to low (e.g., through the transistor B 408).

In one or more examples, the memristor 402 is programmed with a conductance value that corresponds to a lower bound threshold value against which an input current on the data line 410 may be tested. Programming (or resetting) the memristor 402 may include connecting a voltage source 414 to the data line 410. FIG. 4 shows a state in which the voltage source 414 is not connected, which is the state of the lower bound ACAM component 400 during normal operation, after the memristor 402 has been programmed. In one or more examples, connecting the voltage source 414 applies a bias to the gate terminal of the transistor A to provide a voltage V_{write} to the lower bound ACAM component 400 in order to program the conductance of the memristor 402. Once programmed, the conductance of the memristor 402, in conjunction with the characteristics of the transistors (e.g., 404, 408) corresponds to a lower bound threshold current value.

In one or more examples, a voltage on the match line 406 is pre-charged to high using an appropriate circuit (not shown), and the data line 410 is also pre-charged to high (e.g., via charging the capacitor 416 to an initial voltage value). Thus, the match line 406 may remain high, as the gate of the transistor B 308 is low, so that the match line does not discharge. In one or more examples, if an input current applied via the data line 410 is above the lower bound input current threshold corresponding to the conductance programmed to the memristor (e.g., the input current is sufficiently high), the data line remains charged, and thus the match line remains charged, thereby indicating a match for the input current (as being above the lower bound threshold). In one or more examples, the data line, and thus the match line, remain high because when the input current is sufficiently high, the current pull down component 418 is not capable of discharging the data line to a point where the match line is discharged. In one or more examples, if the input current applied via the data line 410 is below the lower bound input current threshold corresponding to the conductance programmed to the memristor, data line 410 is discharged (e.g., via the current pull down component 418), and thus the match line 406 will discharge, indicating a mismatch. In one or more examples, this is because when the input current is sufficiently small, the data line is discharged to a point where the current in the circuit branch with the memristor 402 is sufficiently low that the gate of the transistor B 408 is high, and, therefore, the match line 406 is discharged. In one or more examples, the lower bound ACAM component 400 may also be configure to implement a “don’t care” state by programming the memristor such that the match line is not discharged.

Although FIG. 4 shows an example lower bound ACAM component that uses a memristor as a programmable element, one of ordinary skill in the art, having the benefit of this Description, will appreciate that other programmable elements (e.g., resistive elements) may be used without departing from the scope of examples disclosed herein.

In one or more examples, the upper bound ACAM component 300 of FIG. 3 and the lower bound ACAM component 400 may be used on conjunction with one another as part of a 4T2M ACAM cell for implementing a range against which an input current may be tested, with the upper bound ACAM component 300 setting the upper bound of the range, and the lower bound ACAM component 400 setting the lower bound of the range. In such a configuration, two data lines, with the other components corresponding thereto, may be used to separately apply an input current to the two ACAM components. In one or more examples, if the input current value falls within the range corresponding to the values programmed to the memristors of the upper bound and lower bound components, the match line, which is connected to a terminal of the transistor B of both components, remains high, indicating a match. In one or more examples, if the input current value is outside the range corresponding to the values programmed to the memristors of the upper bound and lower bound components, the match line, which is connected to a terminal of the transistor B of both components, is pulled low, indicating a mismatch.

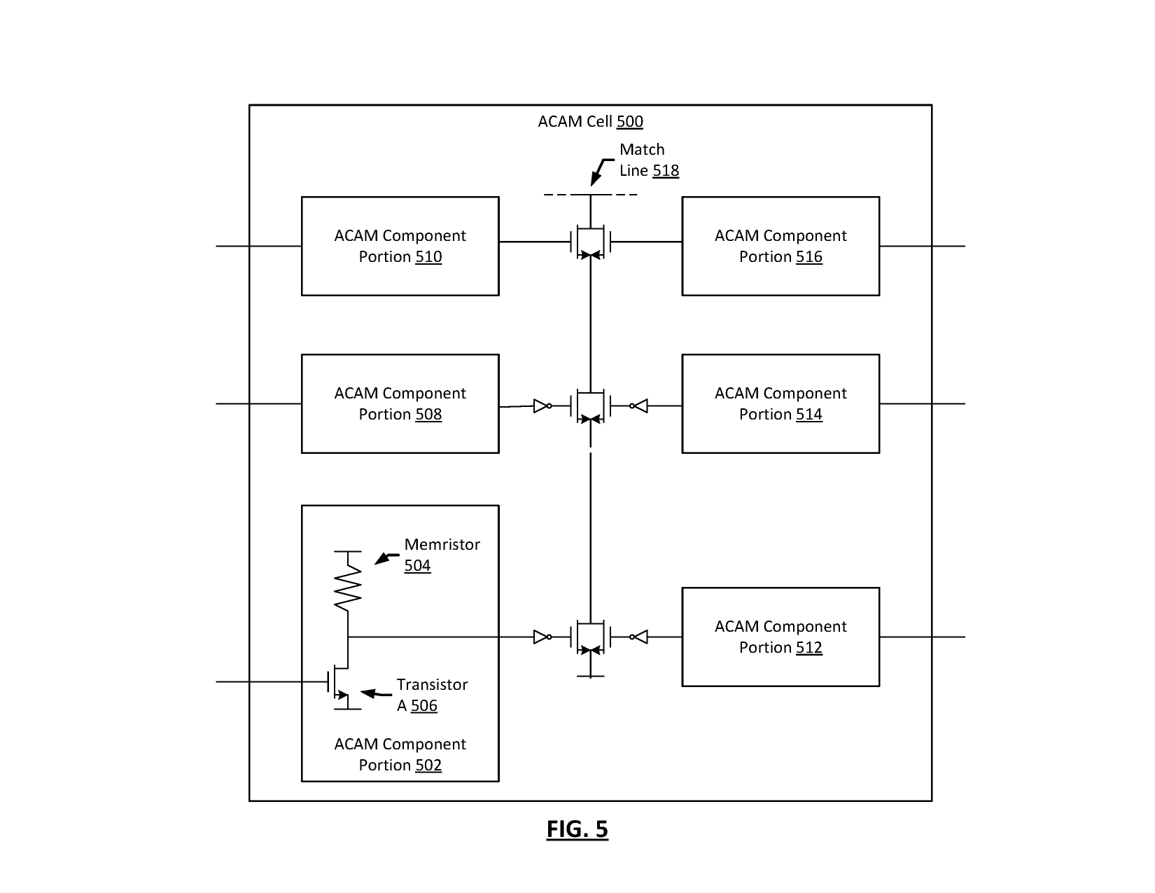

FIG. 5 is a block diagram of an ACAM cell for general computing, in accordance with to one or more examples disclosed herein. As shown in FIG. 5, the ACAM cell 500 may store multiple ranges via multiple ACAM components, which may include various ACAM component portions (e.g., the ACAM component portion 502, the ACAM component portion 508, the ACAM component portion 510, the ACAM component portion 512, the ACAM component portion 514, the ACAM component portion 516).

In one or more examples, each of the ACAM component portions (e.g., 102, 208, 510, 214, 214, 516) may include a transistor (e.g., the transistor A 506) that has a gate terminal coupled to a data line (not shown) to which an input current may be applied, and thus is connected to various other components (not shown) (e.g., a current source, a voltage source, a capacitor, and/or a current pulldown component), as discussed above in the descriptions of FIG. 3 and FIG. 4. In one or more examples, the ACAM cell 500 shown in FIG. 5 may be used to perform four bit, one variable computations, four bit, two variable computations, and/or eight bit, one variable computations. In one or more examples, such computations may be performed by configuring some of the ACAM component portions (e.g., 102, 208, 510, 214, 214, 516) as upper bound ACAM components, and other ACAM component portions as lower bound ACAM component portions, with inverters included between a subset of the ACAM component portions and the transistors operatively connected to the match line 518.

In one or more examples, the ACAM component portion 502 includes the memristor 504 and the transistor A 506, which, when combined with the transistor shown in FIG. 5 as connected to the memristor 504 and a terminal of the transistor A 506, form a 2T1M ACAM component. Although not separately illustrated in FIG. 5, each of the other component portions similarly include a memristor and a transistor, such that each ACAM component portion and additional transistor to which such portions are coupled form ACAM components of the ACAM cell 500.

In one or more examples, to implement the ACAM cell 500 for the aforementioned various computing types, the various memristors of the ACAM component portions may be configured to implement either upper or lower bounds, or be configured to implement don’t care state.

As a first example, to implement computation of at least a portion of a one variable function, the ACAM components 502, 510, 512, and 516 may be set to maximum configurable upper or lower bounds to implement don’t care state, and the ACAM component portions 508 and 514 may be configured to implement an upper bound and lower bound against which an input current value may be compared to test whether an input variable is within the range corresponding to the values programmed to the memristors included in the ACAM component portions. As another example, separate input currents (e.g., representing two variables of a function) may be applied to different ACAM component portions to be tested against separate ranges implemented by the ACAM component portions. As another example, the least significant bits of a variable (e.g., an eight bit variable) may be provided to some of the ACAM component portions, and the most significant bits of a variable may be provided to the other ACAM component portions, with the ACAM component portions implementing boundaries of a range in two parts (e.g., corresponding to the most and least significant bits).

It should be appreciated that FIG. 5 merely shows an example ACAM cell 500 that may be used to implement various modes of computing based on the configuration of the circuitry therein and the values programmed to the memristors, but that a particular ACAM cell may be configured with any number of transistors and/or memristors for implementing various computing modes without departing from the scope of examples disclosed herein.

In the above description of the figures, any component described with regard to a figure, in various examples described herein, may be equivalent to one or more same or similarly named and/or numbered components described with regard to any other figure. For brevity, descriptions of these components may not be repeated with regard to each figure. Thus, each and every example of the components of each figure is incorporated by reference and assumed to be optionally present within every other figure having one or more same or similarly named and/or numbered components. Additionally, in accordance with various examples described herein, any description of the components of a figure is to be interpreted as an optional example, which may be implemented in addition to, in conjunction with, or in place of the examples described with regard to a corresponding one or more same or similarly named and/or numbered component in any other figure.

Throughout the application, ordinal numbers (e.g., first, second, third) may be used as an adjective for an element (i.e., any noun in the application). The use of ordinal numbers is not to imply or create any particular ordering of the elements, nor to limit any element to being only a single element unless expressly disclosed, such as by the use of the terms "before", "after", "single", and other such terminology. Rather, the use of ordinal numbers is to distinguish between the elements. By way of an example, a first element is distinct from a second element, and the first element may encompass more than one element and succeed (or precede) the second element in an ordering of elements.

As used herein, the phrase operatively connected, or operative connection, means that there exists between elements/components/devices a direct or indirect connection that allows the elements to interact with one another in some way. For example, the phrase ‘operatively connected’ may refer to any direct (e.g., wired directly between two devices or components) or indirect (e.g., wired and/or wireless connections between any number of devices or components connecting the operatively connected devices) connection. Thus, any path through which information may travel may be considered an operative connection.

While examples discussed herein have been described with respect to a limited number of examples, those skilled in the art, having the benefit of this disclosure, will appreciate that other examples can be devised which do not depart from the scope of examples as disclosed herein. Accordingly, the scope of examples described herein should be limited only by the attached claims.

What is claimed is:

1. An analog content addressable memory (ACAM) component, comprising:
a plurality of transistors; and
a memristor, wherein:
a gate terminal of a first transistor of the plurality of transistors is coupled to a data line for applying an input current,
another terminal of the first transistor is coupled to the memristor and a gate terminal of a second transistor,
another terminal of the second transistor is coupled to a match line, and
the ACAM component is configured to provide a match result based on the input current and a value programmed to the memristor.

2. The ACAM component of claim 1, wherein the match line is pre-charged to a high value prior to application of the input current.

3. The ACAM component of claim 1, wherein the data line is pre-charged to a high value prior to application of the input current.

4. The ACAM component of claim 3, wherein the data line is also coupled to a capacitor configured to hold the data line at the high value.

5. The ACAM component of claim 1, wherein:
the value programmed to the memristor corresponds to an upper bound value, and
the input current being above the upper bound value causes a discharge of the match line to indicate a mismatch.

6. The ACAM component of claim 1, wherein:
the value programmed to the memristor corresponds to a lower bound value, and
the input current being below the lower bound value causes a discharge of the match line to indicate a mismatch.

7. The ACAM component of claim 1, wherein:
the ACAM component comprises a first portion of an ACAM cell,
the ACAM cell comprises a second portion,
the first portion comprises the memristor programmed to correspond to an upper bound value, and
the second portion comprises a second memristor programmed to correspond to a lower bound value.

8. The ACAM component of claim 7, wherein the ACAM cell is configured to test the value of the input current to determine whether the input current is within a range defined by the upper bound value and the lower bound value.

9. The ACAM component of claim 1, wherein:
the ACAM component is at least a portion of an ACAM cell, and
the ACAM cell is one of a plurality of ACAM cells of an ACAM array.

10. The ACAM component of claim 9, wherein the ACAM array is configured to execute at least a portion of a machine learning (ML) model.

11. The ACAM component of claim 10, wherein the ML model is a decision tree ML model.

12. The ACAM component of claim 10, wherein:
the input current is one of a plurality of input currents received by the ACAM array, and
the plurality of input currents correspond to output currents from a dot product engine configured to perform matrix-vector multiplication.

13. The ACAM component of claim 1, wherein the data line coupled to the gate terminal of the first transistor is also detachably coupled to a voltage source that, when coupled, biases the ACAM component with a voltage used to program the memristor.

14. The ACAM component of claim 1, wherein the ACAM component is one of a plurality of ACAM components of an ACAM cell configured to implement a plurality of computing modes.

15. An ACAM device, comprising:
a first ACAM component comprising:
a first plurality of transistors; and
a first memristor, wherein:
a gate terminal of a first transistor of the first plurality of transistors is coupled to a first data line for applying an input current,
another terminal of the first transistor is coupled to the first memristor and a gate terminal of a second transistor of the first plurality of transistors,
another terminal of the second transistor is coupled to a match line, and
the first ACAM component is configured to provide a first partial match result based on the input current and a first value programmed to the first memristor; and
a second ACAM component comprising:
a second plurality of transistors; and
a second memristor, wherein:
a gate terminal of a third transistor of the second plurality of transistors is coupled to a second data line for applying the input current,
another terminal of the third transistor is coupled to the second memristor and a gate terminal of a fourth transistor of the second plurality of transistors,
another terminal of the second transistor is coupled to the match line,
the second ACAM component is configured to provide a second partial match result based on the input current and a second value programmed to the second memristor.

16. The ACAM device of claim 15, wherein:
the first partial match result indicates a first match when the first ACAM component does not discharge the match line,
the second partial match result indicates a second match when the second ACAM component does not discharge the match line, and
the ACAM device indicates a match based on the first match and the second match.

17. The ACAM device of claim 15, wherein:
the first ACAM component is an upper bound ACAM component, and
the second ACAM component is a lower bound ACAM component.

18. The ACAM device of claim 15, wherein the first ACAM component and the second ACAM component are portions of an ACAM cell of the ACAM device.

19. The ACAM device of claim 18, wherein the ACAM cell is part of an ACAM array of the ACAM device.

20. The ACAM device of claim 19, wherein the ACAM array is configured to execute at least a portion of a machine learning (ML) model.
